(19) United States
(12) Patent Application Publication
(10) Pub. No.: US 2017/0190582 A1
(43) Pub. Date: Jul. 6, 2017

(54) Novel Methods To Grow Two Dimensional Nano-Materials By Using Solid-State Materials as Feedstock

(71) Applicants: Wenjie Fu, Chengdu (CN); Wei Zheng, Williamsburg, VA (US)

(72) Inventors: Wenjie Fu, Chengdu (CN); Wei Zheng, Williamsburg, VA (US)

(21) Appl. No.: 15/396,740

(22) Filed: Jan. 2, 2017

Related U.S. Application Data
(60) Provisional application No. 62/275,307, filed on Jan. 6, 2016.

(51) Int. Cl. C01B 31/02; C23C 16/511; C23C 16/26

(52) U.S. Cl. CPC C01B 31/0446; C01B 31/04; C23C 16/511; C23C 16/26; B82Y 40/00

(57) ABSTRACT

This invention is particularly addressing a novel method to grow two dimensional carbon nanomaterials. Using our technologies, only solid state carbon sources are used as feedstock to grow this kind of carbon nanomaterials, while no hydrocarbon gases or other carbon contained gases are required as feedstock. This invention can also be applied to grow non-carbon-based two dimensional nanomaterials, with obvious advantages of reducing manufacturing cost and enhancing growth rate.

### CROSS-REFERENCE TO RELATED APPLICATIONS

This is the Nonprovisional application for a former provisional application with the same title, submitted on Jan. 6, 2016. EFS ID: 24538619, Application No. 62/275,307

### BACKGROUND

Two dimensional (2D) carbon nano-materials (or nanomaterials) are carbon crystals in a scale of nanometers. The 2D carbon nanomaterials are made of a single to a few layers of graphene. If a carbon nanomaterial is being thickened to more than tens of nanometers, it has graphitic crystal structure.

This invention is particularly addressing to free-standing two dimensional carbon nanostructures, which include but are not only limited to Fluffy Graphene, Carbon Nanosheets, Carbon Nanowalls, Carbon Nanoflakes, Vertically Free-standing Graphene, Graphene Flowers, or Petals made of Graphene.

This invention can also be applied to grow non-carbon-based two dimensional nanomaterials, with obvious advantages of reducing manufacturing cost and enhancing growth rate.

### SUMMARY OF THE INVENTION

This invention teaches how to grow free-standing two-dimensional carbon nanomaterials, especially vertically free-standing graphene, via non-conventional methods. Using our technologies, no more hydrocarbon gases or other carbon contained gases are necessarily required to grow the graphene materials.

Simply modifying our invented technologies, a man familiar with plasma technology can use this invention to grow other two-dimensional nanomaterials via a solid-state feedstock (a.k.a. precursor).

It is well known that free-standing carbon nanomaterials can be synthesized via methods of Chemical Vapor Deposition (CVD). Feedstock precursors are introduced into a process chamber in vapor phase. To enhance growth reaction, plasma technology is usually applied. This process is called plasma enhanced CVD (PE-CVD) method. Radio-Frequency (RF) electromagnetic wave, microwave, direct current (DC), hot filaments, parallel plates can generate plasma during reaction processes.

Conventional methods must use expensive and flammable gases, such as a hydrocarbon gas as feedstock. Carbon atoms are extracted from those hydrocarbon gases to grow graphene materials. Usually, hydrogen or other reductive gases are required during the process.

Our novel methods only use a carbon solid as feedstock. None of carbon based feedstock gas is required. Furthermore, neither hydrogen nor other reductive gases is required during our invented processes.

Choosing a solid-state feedstock has tremendous advantages over a gas feedstock. To manage gas flow and process pressure, it increases process cost and requires extra engineering hardware and labors.

Carbon bulk materials in solid-state are abundant in natural resources, and is easy-to-adopt as a feedstock. Carbon atoms are extracted from the solid-state carbon bulk materials directly.

The method to grow free-standing carbon nanometerials which only uses solid-state feedstock, has never been reported in academic or industry articles.

### BRIEF DESCRIPTION OF THE DRAWINGS

FIG. 1 is a schematic cross-sectional view of an apparatus, which uses a planar-coil-antenna to generate Inductive-Coupled-Plasma (ICP). The apparatus can manufacture two-dimensional carbon nanomaterials.

FIG. 2 shows more possible positions, where solid-state carbon sources can be disposed in the planar-coil-antenna-incorporated apparatus, beside one position in FIG. 1.

FIG. 3 is a schematic cross-sectional view of an apparatus, which uses a helical-coil-antenna to generate Inductive-Coupled-Plasma (ICP). The apparatus can manufacture two-dimensional carbon nanomaterials.

FIG. 4 shows more possible positions, where solid-state carbon sources can be disposed in the helical-coil-antenna-incorporated apparatus, beside one position in FIG. 3.

FIG. 5 is a schematic cross-sectional view of an apparatus, which uses a planar-plate-antenna to generate Capacitive-Coupled-Plasma (CCP). The apparatus can manufacture two-dimensional carbon nanomaterials.

FIG. 6 shows more possible positions, where solid-state carbon sources can be disposed in the planar-plate-antenna-incorporated apparatus, beside one position in FIG. 5.

FIG. 7 is a schematic cross-sectional view of an apparatus, which uses microwave field in transverse magnetic (TM) mode to generate plasma. The apparatus can manufacture two-dimensional carbon nanomaterials.

FIG. 8 shows more possible positions, where solid-state carbon sources can be disposed in the TM mode microwave waveguide incorporated apparatus, beside one position in FIG. 7.

FIG. 9 is a schematic cross-sectional view of an apparatus, which uses microwave field in transverse electric (TE) mode to generate plasma. The apparatus can manufacture two-dimensional carbon nanomaterials.

FIG. 10 shows more possible positions, where solid-state carbon sources can be disposed in the TM mode microwave waveguide incorporated apparatus, beside one position in FIG. 9.

FIG. 11 is a schematic cross-sectional view of an apparatus, which uses microwave field in transverse electromagnetic (TEM) mode to generate plasma. The apparatus can manufacture two-dimensional carbon nanomaterials.

### DETAILED DESCRIPTION OF THE INVENTION

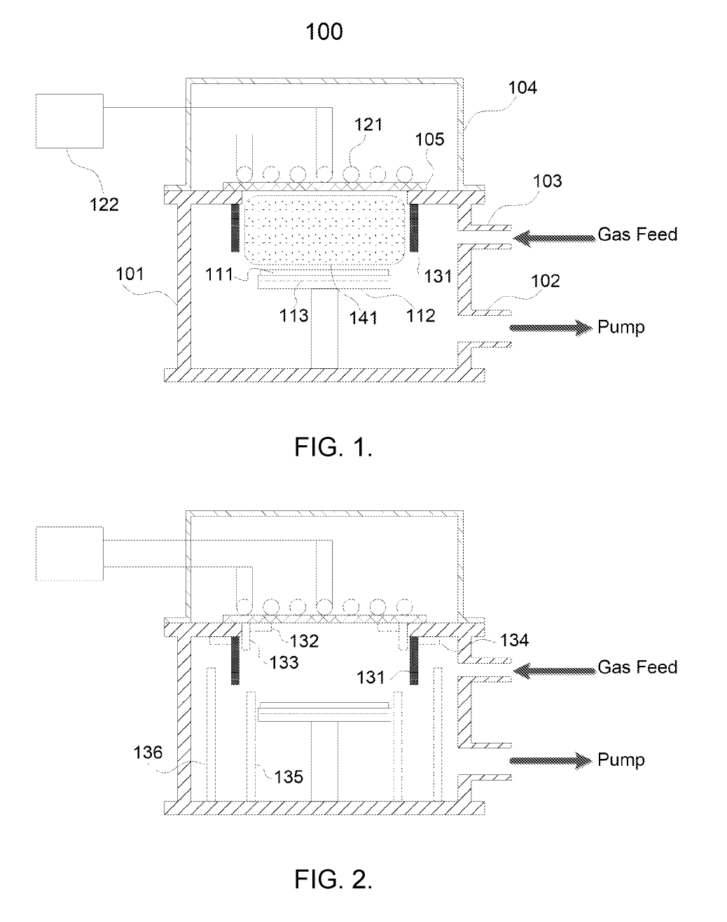

FIG. 1 is a schematic cross-sectional view showing structure of a planar-coil ICP plasma apparatus to manufacture the two-dimensional carbon nanomaterials. With reference to FIG. 1, the apparatus 100 includes a vacuum chamber 101, an exhaust port 102, a gas inlet 103, a shield box 104, a RF power radiation window 105, a substrate 111, a holder 112, a heater 113, a planar-coil antenna to radiate RF power 121, a RF power source with matching circuit 122, and a solid-state carbon source 131.

The vacuum chamber 101 is made of metal and connected to a vacuum pump via the exhaust port 102. The vacuum chamber 101 is electrically grounded.

The gas inlet 103 supplies a non-hydrocarbon gas, such as Argon (Ar) gas, from a gas container (not shown), into the vacuum chamber 101.

The shield box 104 is made of metal and positioned on the upper side of the vacuum chamber 101. The shield box 104 makes contact with the top plate of vacuum chamber 101 and electrically grounded.

The RF power window 105 is made of RF electromagnetic wave transparent material, such as quartz glass, etc. The RF window 105 makes contact with the vacuum chamber 101 via a vacuum sealing.

The holder 112 is disposed in the vacuum chamber 101. The heater 113 is positioned in the holder 112. The substrate 111 is disposed on top of the holder 112. The holder 112 supports the substrate 111. The heater 113 heats the substrate 111 to a desired temperature.

The planar-coil antenna 121 to radiate RF power is positioned in the shield box 105, and on the upper side of the RF window 105. The planar-coil RF antenna 121 is connected the RF power source with matching circuit 122.

The RF power source with matching circuit 122 supplies a high frequency electromagnetic wave of 13.56 MHz, for example, to the planar-coil antenna 121, and suppresses reflection of the high frequency electromagnetic wave backward from the planar antenna 121.

The solid-state carbon source 131 is positioned in the vacuum chamber 101, and between RF window 105 and substrate 111.

In the apparatus 100, plasma 141 is generated in the vacuum chamber 101, and under the RF window 105. That is, as shown in FIG. 1, when the RF electromagnetic wave is generated around the RF antenna 121, electrons are accelerated by the induced electric field, and the gas in the vacuum chamber 101 is ionized. The plasma 141 is generated under the RF window, and reacts with the substrate 111.

FIG. 2 shows more possible positions of solid-state carbon sources, beside the one disposed in FIG. 1. The positions of solid-state carbon source can be selected from position 131, 132, 133, 134, 135, 136, and a combination thereof.

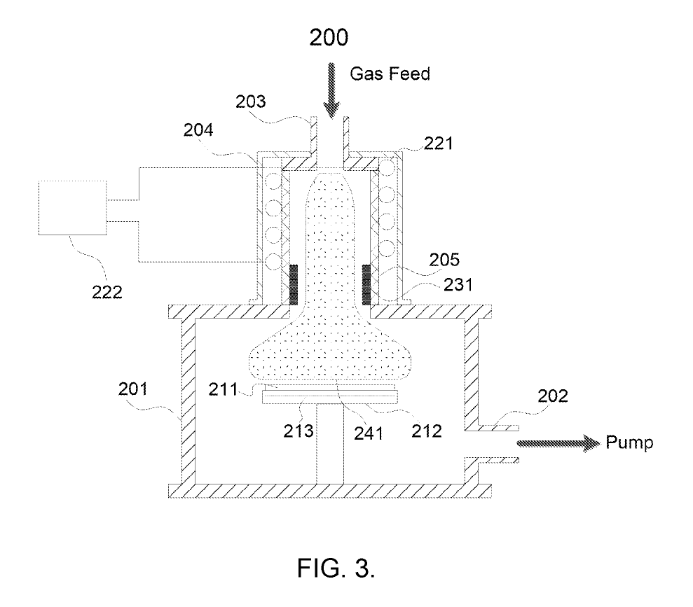

FIG. 3 is a schematic cross-sectional view showing structure of a helical-coil ICP plasma apparatus to manufacture the two-dimensional carbon nanomaterials. With reference to FIG. 3, the apparatus 200 includes a vacuum chamber 201, a gas exhaust port 202, inlet 203, a shield box 204, a tube 205, a substrate 211, a holder 212, a heater 213, a helical RF antenna 221, a RF power source with matching circuit 222, and a solid-state carbon source 231.

The vacuum chamber 201 is made of metal and connected to a vacuum pump via the exhaust port 202. The vacuum chamber 201 is electrically grounded.

The gas inlet 203 supplies a non-carbon gas, such as Argon (Ar) gas, from a gas container (not shown), into the vacuum chamber 201. The gas inlet 203 makes contact with the tube 205 via a vacuum sealing.

The tube 205 is made of RF electromagnetic wave transparent material, such as quartz glass, etc. The tube 205 makes contact with the vacuum chamber 201 via a vacuum sealing.

The shield box 204 is made of metal and positioned on the upper side of the vacuum chamber 201, and outside of the helical RF antenna 221. The shield box 205 makes contact with the top plate of vacuum chamber 201 and electrically grounded.

The holder 212 is placed in the vacuum chamber 201. The heater 213 is positioned in the holder 212. The substrate 211 is disposed on top of the holder 212. The holder 212 supports the substrate 211. The heater 213 heats the substrate 211 to a desired temperature.

The helical RF antenna 221 is positioned in the shield box 205, and on the outside of the tube 205. The helical RF antenna 221 is connected to the RF power source with matching circuit 222.

The RF power source with matching circuit 222 supplies a high frequency electromagnetic wave of 13.56 MHz, for example, to the helical RF antenna 221, and suppresses reflection of the high frequency electromagnetic wave back from the helical RF antenna 221.

The solid-state carbon source 231 is positioned in the tube 205, or in the vacuum chamber 201.

In the apparatus 200, plasma 241 is generated in the tube 205, and transported into the vacuum chamber 201 via gas pressure. That is, as shown in FIG. 3, when the RF electromagnetic wave is generated around the RF antenna 221, electrons are accelerated by the induced electric field and the gas in the tube 205 is ionized. The plasma 241 is transported into the vacuum chamber 201 via gas pressure, and can reach the substrate 211.

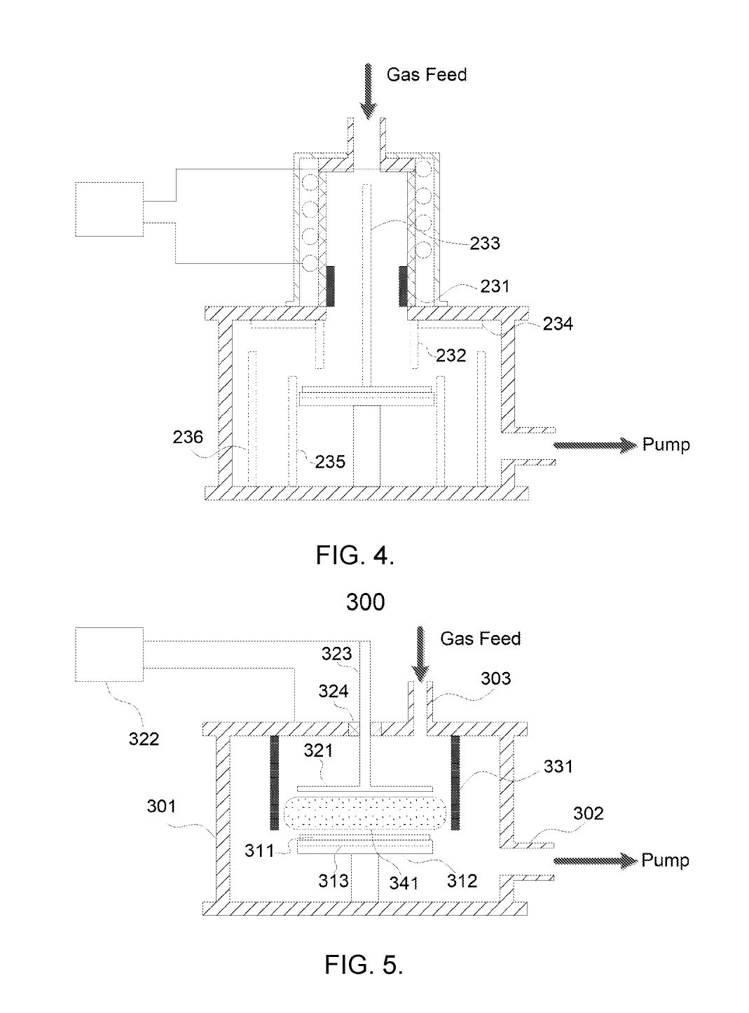

FIG. 4 shows more possible positions of solid-state carbon sources, beside the one disposed in FIG. 3. The positions of solid-state carbon source can be selected from position 231, 232, 233, 234, 235, 236, and a combination thereof.

FIG. 5 is a schematic cross-sectional view showing structure of a CCP plasma apparatus to manufacture the two-dimensional carbon nanomaterials. With reference to FIG. 5, the plasma apparatus 300 includes a vacuum chamber 301, an exhaust port 302, a gas inlet 303, a substrate 311, a holder 312, a heater 313, a RF electrode 321, a RF power source with matching circuit 322, a RF transmission line 323, a RF connector 324, and a solid-state carbon source 331.

The vacuum chamber 301 is made of metal and connected to a vacuum pump via the exhaust port 302. The vacuum chamber 301 is electrically grounded.

The gas inlet 303 supplies a non-carbon gas, such as Argon (Ar) gas, from a gas container (not shown), into the vacuum chamber 301.

The holder 312 is placed in the vacuum chamber 301. The heater 313 is positioned in the holder 312. The substrate 311 is disposed on top of the holder 312. The holder 312 supports the substrate 311. The heater 313 heats the substrate 311 to a desired temperature.

The RF electrode 321 is positioned in the vacuum chamber 301, and parallel to the holder 312. The RF electrode 321 is electrically connected to the RF power source with matching circuit 322 via RF transmission line 323.

The RF connector 324 is made of insulator. The RF transmission line 323 is positioned through the RF connector 324, and makes contact with the RF connector 324 via a vacuum sealing. The RF connector is positioned on the wall of the vacuum chamber 301, and in contact with the vacuum chamber 301 via vacuum sealing.

The RF power source with matching circuit 322 supplies a high frequency electromagnetic wave of 13.56 MHz, for example, to the RF electrode 321, and suppresses reflection of the high frequency electromagnetic wave backward from the RF electrode 321.

The solid-state carbon source 331 is positioned in the vacuum chamber 301, and around the holder 312 and planar RF electrode 321.

In the plasma apparatus 300, plasma 341 is generated in the vacuum chamber 301, and between the RF electrode 321 and the substrate 311. That is, as shown in FIG. 5, when the RF electromagnetic wave is generated around the RF electrode 321, electrons are accelerated by the coupled electric field, and the gas in the vacuum chamber 301 is ionized. The plasma 341 is generated between the RF electrode 321 and the substrate 311, and can reach the substrate 311.

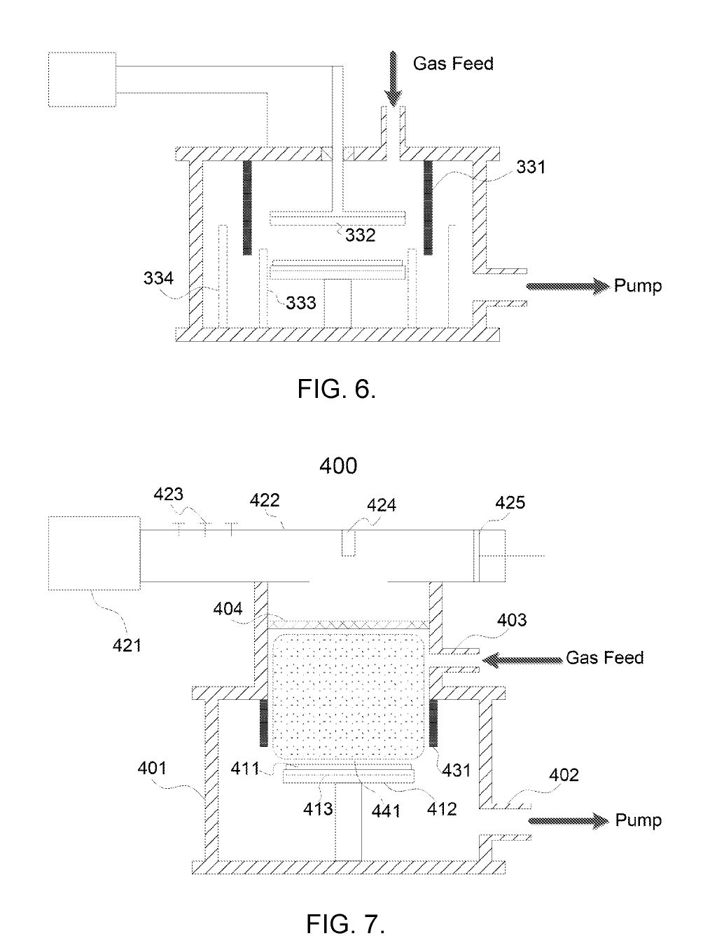

FIG. 6 shows more possible positions of solid-state carbon sources, beside the one disposed in FIG. 5. The positions of solid-state carbon source can be selected from position 331, 332, 333, 334, and a combination thereof.

FIG. 7 is a schematic cross-sectional view showing structure of a TM microwave plasma apparatus to manufacture the two-dimensional carbon nanomaterials. With reference to FIG. 7, the plasma apparatus 400 includes a vacuum chamber 401, an exhaust port 402, a gas inlet 403, a microwave window 404, a substrate 411, a holder 412, a heater 413, a microwave power source 421, a microwave waveguide 422, a match tuner 423, a load tuner 424, a microwave adapter 425, and a solid-state carbon source 431.

The vacuum chamber 401 is made of metal and connected to a vacuum pump via the exhaust port 402. The vacuum chamber 401 is electrically connected to a ground node.

The gas inlet 403 supplies a non-carbon gas, such as Argon (Ar) gas, from a gas container (not shown), into the vacuum chamber 401.

The microwave window 404 is made of microwave transparent material, such as quartz glass, etc. The microwave window 404 makes contact to the vacuum chamber 401 via a vacuum sealing.

The holder 412 is placed in the vacuum chamber 401. The heater 413 is positioned in the holder 412. The substrate 411 is disposed on top of the holder 412. The holder 412 supports the substrate 411. The heater 413 heats the substrate 411 to a desired temperature.

The microwave power source 421 supplies a microwave of 2.45 GHz, for example, to the microwave waveguide 422. The microwave adapter 425 transmits the microwave from the microwave waveguide 422 into the vacuum chamber 401 via the microwave window 404. In the vacuum chamber 401, microwave field is in a TM mode.

The match tuner 423 and load tuner 424 suppress reflection of the microwave backward from the microwave adapter 425.

The solid-state carbon source 431 is positioned around the substrate 411 in the vacuum chamber.

In the plasma apparatus 400, the plasma 441 is generated under the microwave window 404 in the vacuum chamber 401. That is, as shown in FIG. 7, when the microwave is generated from microwave power source 421, and transmitted via the microwave waveguide 422 and microwave adapter 425 electrons are accelerated by the TM mode microwave, and the gas in the vacuum chamber 401 is ionized. The plasma 441 is generated under the microwave window, and can reach the substrate 411.

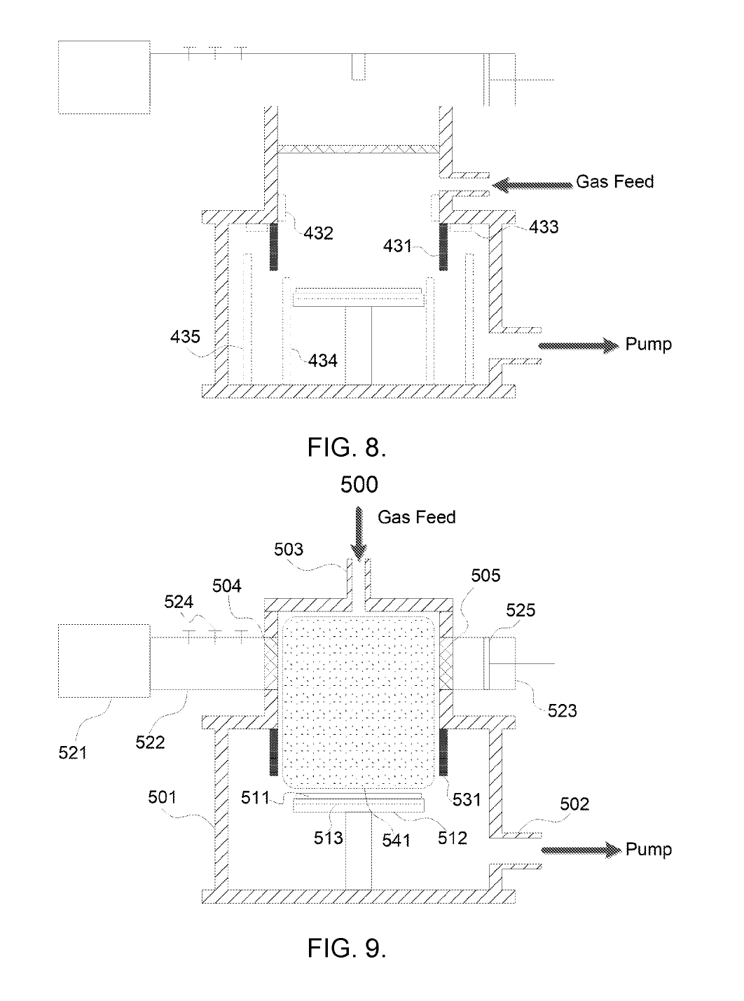

FIG. 8 shows more possible positions of solid-state carbon sources, beside the one disposed in FIG. 7. The positions of solid-state carbon source can be selected from position 431, 432, 433, 434, 435, and a combination thereof.

FIG. 9 is a schematic cross-sectional view showing structure of a TE microwave plasma apparatus to manufacture the two-dimensional carbon nanomaterials. With reference to FIG. 9, the plasma apparatus 500 includes a vacuum chamber 501, an exhaust port 502, a gas inlet 503, a microwave input window 504, a microwave load window 505, a substrate 511, a holder 512, a heater 513, a solid-state carbon source 531, a microwave power source 521, a microwave input waveguide 522, a microwave load waveguide 523, a match tuner 524, a load tuner 525, and a solid-state carbon source 531.

The vacuum chamber 501 is made of metal and connected to a vacuum pump via the exhaust port 502. The vacuum chamber 501 is electrically grounded.

The gas inlet 503 supplies a non-carbon gas, such as Argon (Ar) gas, from a gas container (not shown), into the vacuum chamber 501.

The microwave input window 504 and microwave load window 505 are made of microwave transparent material, such as quartz glass, etc. The microwave input window 504 and microwave load window 505 make contact with the vacuum chamber 501 via a vacuum sealing.

The holder 512 is placed in the vacuum chamber 501. The heater 513 is positioned in the holder 512. The substrate 511 is disposed on top of the holder 512. The holder 512 supports the substrate 511. The heater 513 heats the substrate 511 to a desired temperature.

The microwave power source 521 supplies a microwave of 2.45 GHz, for example, to the microwave input waveguide 522. The microwave input waveguide makes contact with the microwave input window 504. The microwave input waveguide 522 transmits the microwave into the vacuum chamber 501 via the microwave input window 504. In the vacuum chamber 501, microwave field is in a TE mode.

The microwave load waveguide 523 makes contact with the microwave load window 505. The match tuner 524 and load tuner 525 suppress reflection of the microwave back from the vacuum chamber 501.

The solid-state carbon source 531 is positioned around the substrate 511 in the vacuum chamber 501.

In the plasma apparatus 500, plasma 541 is generated between the microwave input window 504 and microwave load window 505 in the vacuum chamber 501. That is, as shown in FIG. 9, when the microwave is generated from microwave power source 521, and transmitted via the microwave waveguide 522 and microwave input window 504, electrons are accelerated by the TE mode microwave, and the gas in the vacuum chamber 501 is ionized. The plasma 541 is generated between the microwave input window 504 and microwave load window 505. The plasma 541 is transported to the surface of the substrate 511 via gas pressure.

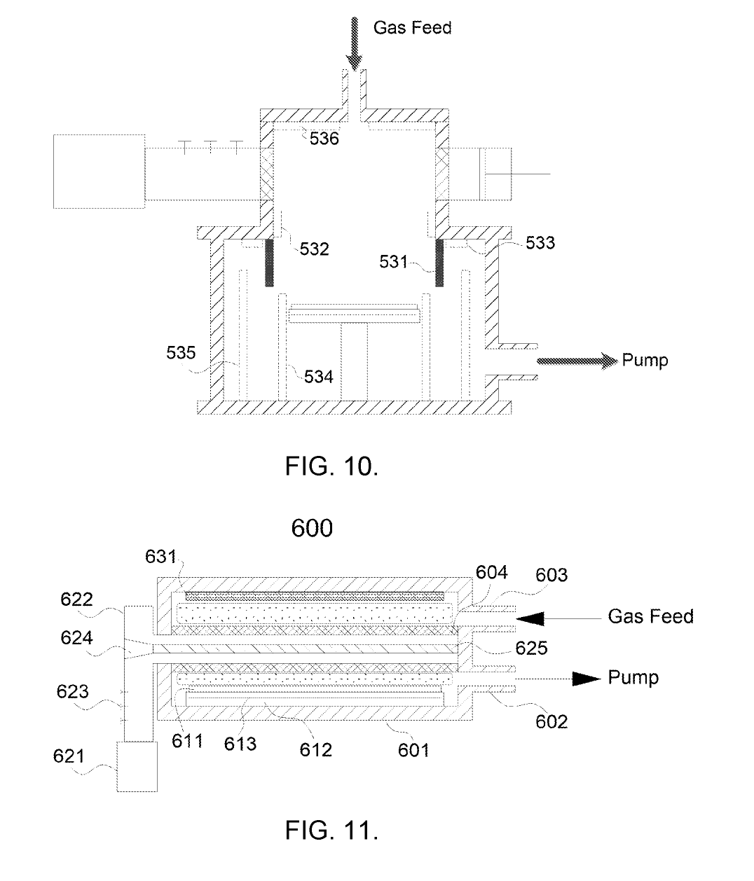

FIG. 10 shows more possible positions of solid-state carbon source, beside the one disposed in FIG. 9. The positions of solid-state carbon source can be selected from position 531, 532, 533, 534, 535, 536, and a combination thereof.

FIG. 11 is a schematic cross-sectional view showing structure of a TEM microwave plasma apparatus to manufacture the two-dimensional carbon nanomaterials. With reference to FIG. 11, the plasma apparatus 600 includes a vacuum chamber 601, an exhaust port 602, a gas inlet 603, a microwave waveguide tube 604, a substrate 611, a holder 612, a heater 613, a microwave power source 621, a microwave input waveguide 622, a match tuner 623, a microwave adapter 624, a cylindrical antenna 625, and a solid-state carbon source 631.

The vacuum chamber 601 is made of metal and connected to a vacuum pump via the exhaust port 602. The vacuum chamber 601 is electrically grounded.

The gas inlet 603 supplies a non-carbon gas, such as Argon (Ar) gas, from a gas container (not shown), into the vacuum chamber 601.

The microwave waveguide tube 604 is made of microwave transparent material, such as quartz glass, etc. The waveguide tube 604 is positioned in the vacuum chamber 601 and makes contact with the vacuum chamber 601 via a vacuum sealing.

The holder 612 is placed in the vacuum chamber 601. The heater 613 is positioned in the holder 612. The substrate 611 is disposed on top of the holder 612. The holder 612 supports the substrate 611. The heater 613 heats the substrate 611 to a desired temperature.

The microwave power source 621 supplies a microwave of 2.45 GHz, for example, to the microwave input waveguide 622. The microwave adapter 624 transmits microwave from the microwave input waveguide 622 to the cylindrical antenna 625. The cylindrical antenna 625 radiates microwave to the vacuum chamber 601 via the waveguide tube 604. In the vacuum chamber 601, microwave field is in a TEM mode.

The match tuner 623 suppresses reflection of the microwave backward from the vacuum chamber 601.

The solid-state carbon source 631 is positioned in the vacuum chamber 601, and face to the substrate 611.

In the plasma apparatus 600, plasma 641 is generated around the microwave waveguide tube 604 in the vacuum chamber 601. That is, as shown in FIG. 10, when the microwave is generated around the cylindrical antenna 625, electrons are accelerated by the TEM mode microwave, and the gas in the vacuum chamber 601 is ionized. The plasma 641 is generated around the microwave tube 604 and can reach the substrate 611 and solid-state carbon source 631.

1. is a method of growing two dimensional carbon nanomaterials, comprising:
a first process of disposing a solid-state carbon source in a vacuum container (a.k.a. vacuum vessel or vacuum process chamber),
a second process of disposing a growth substrate in the container,
a third process of pumping down (or evacuate) the container below a desired background pressure A,
a fourth process of heating the substrate to a desired temperature,
a fifth process of introducing a non-carbon, particularly an non-hydrocarbon gas to a desired process pressure B,
a sixth process of applying electromagnetic (e.g. RF, microwave) power to an exciter (e.g. RF antenna, microwave waveguide), and generating plasma inside the vacuum chamber through radiation of the electromagnetic wave/power from the exciter.
The method of claim 1, wherein said the solid-state carbon source is selected from a group consisting of carbon, charcoal, graphite, hydrocarbon solid, oxycarbide, or carbonitride, or fluorocarbon, and a combination thereof.
The method of claim 1, wherein said desired background pressure A is a value lower then 10 mTorr.
The method of claim 1, wherein said non-carbon gas is selected from Argon, or Nitrogen, or other inertia gases, and a combination thereof.
The method of claim 1, wherein said the desired temperature is 500-1200° C.
The method of claim 1, wherein said solid-state carbon source is positioned between substrate and antenna.
The method of claim 1, wherein said desired process pressure B is between 10 mTorr and 10 Torr.
The method of claim 1, wherein said solid-state carbon source has a through hole in the center.
